(19) United States
(12) Patent Application Publication
(10) Pub. No.: US 2023/0399747 A1
(43) Pub. Date: Dec. 14, 2023

(54) PEDESTAL HEATER BLOCK HAVING ASYMMETRIC HEATING WIRE STRUCTURE

(71) Applicant: MECARO CO., LTD., Pyeongtaek-si, Gyeonggi-do (KR)

(72) Inventors: Jun Ho LEE, Pyeongtaek-si, Gyeonggi-do (KR); Dong Chul CHOI, Seoul (KR); Se Hyeok AHN, Pyeongtaek-si, Gyeonggi-do (KR); Myung Kee HONG, Seoul (KR); Jin Man PARK, Pyeongtaek-si, Gyeonggi-do (KR)

(73) Assignee: MECARO CO., LTD., Pyeongtaek-si, Gyeonggi-do (KR)

(21) Appl. No.: 18/248,069

(22) PCT Filed: Oct. 7, 2021
(86) PCT No.: PCT/KR2021/013743

§ 371 Date: Apr. 6, 2023

(30) Foreign Application Priority Data
Oct. 8, 2020 (KR) 10-2020-0130198

(51) Int. Cl. C23C 16/46; C23C 16/458

(52) U.S. Cl. CPC C23C 16/46; C23C 16/4586

(57) ABSTRACT

Disclosed is a pedestal heater block for a chemical vapor deposition machine, in which a structure intended for causing a vacuum to be applied is installed on a surface so that a wafer can be fixed by vacuum absorption, and which comprises: gas supply holes distributed to supply gas for temperature uniformity onto a back side of the wafer; and a hot wire configured to apply heat to the wafer, wherein the hot wire is installed to have higher installation density in a central part of the heater block which is a position corresponding to a central part of the wafer than that in a neighborhood part which is an outer side of the heater block.

### TECHNICAL FIELD

The present invention relates to a pedestal heater block, and more particularly, to a pedestal heater block having an asymmetrical hot-wire structure which causes high temperature uniformity to occur within the heater block.

### BACKGROUND ART

In order to form a semiconductor element and a circuit comprising the same in a semiconductor substrate or a wafer, a semiconductor device has mainly been manufactured through various processes, like diffusion using heat or ion implantation, etc., deposition of a material layer, patterning using photolithography, and so on.

With respect to a method of depositing the material layer, a physical deposition and a chemical vapor deposition, like sputtering, may be used, and a chemical vapor deposition machine may be used in manufacturing equipment of the semiconductor device, which functions to perform the chemical vapor deposition.

The chemical vapor deposition method is a method of forming the material layer, the method causing a material thin-film to be deposited through a chemical process, like absorption, decomposition, and so on, carried out on the substrate heated in such a manner as to inject a thin film material evaporated by carrier gas, or a liquid delivery system (LDS) into a process chamber.

A raw material compound used in this chemical vapor deposition method should has important characteristics: high steam pressure; a liquid compound; evaporation temperature; thermal stability during safekeeping; facility of handling; easy reactivity to a reactant occurring during a process; a simple deposition mechanism; easiness of the removal of by-products; and so on.

In order to form the material thin-film so as to have a uniform thickness and ingredients at the time of depositing and forming the material thin-film through this chemical vapor deposition method, it is required to maintain a process condition, like a deposition temperature, and so on, uniformly throughout the substrate.

FIG. 1 is a cross-sectional view showing the constitution of a pedestal heater block on which a process wafer is put according to a conventional chemical vapor deposition machine. As illustrated therein, the heater block comprises: a base block 10, on a surface of which is put a substrate (not shown in the drawing), and which causes a deposition to be carried out by vacuum absorption; a block back cover 20 combined with the rear of the base block 10; an outer rod 40 functioning as a medium configured to cause the base block 10 and the block back cover 20 to be fixed to a chamber (not shown in the drawing); an inner rod 30 configured to cause the base block 10 and the block back cover 20 to move up and down; a sheath heater 50 configured to apply heat to the base block 10; a vacuum pipe 60 configured to fix the substrate through vacuum absorption; a gas supply pipe 70 configured to supply argon gas which causes heat of the heater block to be uniformly transmitted to the substrate by being discharged onto a back side of the substrate; and a temperature sensor pipe 80 through which a temperature sensor passes, thereby causing a temperature of the base block 10 to be sensed.

However, although the heater block should reach a uniform temperature while causing heat to be transmitted to the wafer as a hot wire is formed in the inside of the heater block, a difference in temperature occurs according to each position of the substrate based on arrangement of the hot wire, so it may become difficult to form a deposited film having a homogeneous feature and a uniform thickness made through the chemical vapor deposition.

FIG. 2 is a plane view showing the arrangement form of an existing hot wire. With respect to this constitution, the arrangement of the hot wire shows that left and right points are symmetrical with respect to the origin centering around one diameter line of a circular heater block 110. Also, it is shown that the hot wire 120 is relatively uniformly distributed in the direction of a neighborhood part and the direction of a central part of the heater block.

In general, since a distribution of the hot wire is uniformly realized in a central part and a neighborhood part of a circular wafer, although it is expected that heat transmission which reaches the wafer from the heater block will also be realized uniformly, and a temperature deviation according to each position of the wafer will not be large, in the real constitution, there is also a case that the temperature of the wafer is found to be low in the central part of the wafer, and a temperature deviation between a place where the temperature is high, and a place where the temperature is low reaches 4° C. to 5° C.

Although this difference in temperature may be regarded as not being large, it is required to reduce this difference within the realms of possibility because the semiconductor element or the circuit, which causes the final result of a process to be realized by just a small difference in thickness of the deposited film resulting from this difference in temperature according to high density integration and miniature of the semiconductor device, may largely be influenced thereby.

In order to solve the problem occurring from the existing heater block, as a result of investigating a phenomenon of the temperature deviation in detail, it could be confirmed that since backside atmospheric-pressure applied onto the back side of the wafer through a vacuum structure of vacuum holes intended for vacuum absorption applied to the heater block in order to cause the wafer to be mounted to the heater block stably, a groove 130 each connected thereto, and so on is very low in about 3 torr, this difference in temperature occurs largely particularly when vacuum absorption force is high, and it could be found that some sections showing a lower temperature than that in the direction of the neighborhood part are clearly formed in the direction of the central part.

### DETAILED DESCRIPTION OF THE INVENTION

### Technical Problem

An object of the present invention is to provide a pedestal heater block which is configured so as to decrease frequency in occurrence of temperature deviations of the wafer which is put on the existing pedestal heater block for the chemical vapor deposition machine as described above.

The other object of the present invention is to provide a pedestal heater block having the constitution of a hot wire capable of causing a temperature deviation to reduce according to each position of the wafer when a chemical vapor deposition process of the wafer is in progress.

### Solution for Solving the Problem

In order to accomplish the aforesaid objects, with respect to a pedestal heater block for a chemical vapor deposition machine according to the present invention, in which vacuum holes are installed in a central part so that a wafer can be fixed through vacuum absorption, and which is configured to cause gas for temperature uniformity to be supplied to a back side of the wafer, it is characteristic in that a hot wire is installed to have higher installation density in a central part of the heater block, which is a position corresponding to a central part of the wafer, than that in a neighborhood part corresponding to an outer side of the heater block on the basis of a position which is in a range of within ½ to ⅘ of a radius, for example, within ⅗ to ⅔ of the radius, more preferably.

According to the present invention, in order to facilitate installation, arrangement of the hot wire may be realized in an asymmetrical form, like a snail form, rather than a form in which left and right points of the hot wire are symmetrical with respect to the origin, and in case that the hot wire is arranged in the asymmetrical form, it may be composed in a cartridge-type heater rather than a sheath-type heater.

According to the present invention, it may be preferable that a main body of the heater block is composed of aluminum or an aluminum alloy having excellent thermal conductivity, and that a coating film intended for enhancing the thermal conductivity is formed on a surface.

According to the present invention, with respect to grooves formed on a surface of the heater block, in order to improve a pressed adhesion when backside pressure applied onto a back side of the wafer during a process is maintained in a range of 3 torr or below, when seen from a section of the groove according to the conventional art, if the groove shows the section similar to a square whose width ranges from 1.2 mm to 1.9 mm, and whose depth ranges from 1.2 mm to 1.9 mm, the groove according to the present invention may be configured in such a form that width is entirely 2 to 6 times larger than depth as the width is formed in a range of about 2.3 mm to 3.0 mm, for example, by increasing up to about 1 to 1.5 times, for example, and the depth is formed in a range of 0.5 mm to 1.0 mm, for example, by reducing up to 0.3 to 0.6 time, for example.

### Effect of the Invention

According to the present invention, even in case that a temperature deviation is caused because the flow of gas for temperature uniformity functioning to uniform the temperature of the whole surface of a substrate is insufficiently realized when vacuum absorption force increases as low pressure, 3 torr or below of the low pressure, for example, is applied to a backside of the substrate during a chemical vapor deposition process in a state of a wafer or the substrate being put on a pedestal heater block, in a central part of the heater block corresponding to a position of the wafer which is easy to cause a low temperature, a heater is installed to have higher installation density than that shown in a neighborhood part, so the heater can cause some much heat to be relatively transmitted to the central part, and heat to be slightly transmitted to the neighborhood part, and accordingly, since the temperature deviation may further reduce throughout the wafer during a deposition process compared with that shown in the conventional art, uniformity of the thickness and the homogeneous feature of a film deposited on the wafer can be improved.

### BRIEF DESCRIPTION OF THE DRAWINGS

FIG. 1 is one side section view for showing the constitution of an existing pedestal heater block for a chemical vapor deposition machine,

FIG. 2 is a schematic plane view showing an example in which a hot wire from the existing pedestal heater block for the chemical vapor deposition machine is installed in balance so that right and left points of the hot wire are symmetrical with respect to the origin,

FIG. 3 is a construct view conceptually and briefly showing a basic constitution of a pedestal heater block according to one exemplary embodiment of the present invention in which a hot wire in a cartridge mode having an asymmetrical structure is adopted,

FIG. 4 is a schematic plane view showing a form in which the hot wire in the cartridge mode is installed in an asymmetrical form according to the exemplary embodiment of the present invention,

FIG. 5 is the camera photographs of thermally burned images showing temperature distributions together so that the temperature distributions can be compared with each other in such a manner as to vary colors according to each temperature at the time of transferring heat to a wafer according to the existing exemplary embodiment, and the exemplary embodiment shown in FIG. 4,

FIG. 6 is a plane view representing a test wafer for measuring a temperature according to each position, and each position for measurement of the temperature when a temperature of the wafer within the chemical vapor deposition machine is fixed to be 300° C. with respect to distributions of the hot wire shown in the existing exemplary embodiment, and distributions of the hot wire shown in the exemplary embodiment of the present invention, and

FIG. 7 is the camera photographs of thermally burned images showing temperature distributions according to each position of the test wafer resulting from some mixing of pressure applied to a process chamber and backside pressure when the temperature of the wafer within the chemical vapor deposition machine is fixed to be 300° C. with respect to the distributions of the hot wire shown in the existing exemplary embodiment, and the distributions of the hot wire shown in the exemplary embodiment of the present invention.

### MODE FOR CARRYING OUT THE INVENTION

Hereinafter, the present invention is described in more detail based on exemplary embodiments thereof with reference to the drawings.

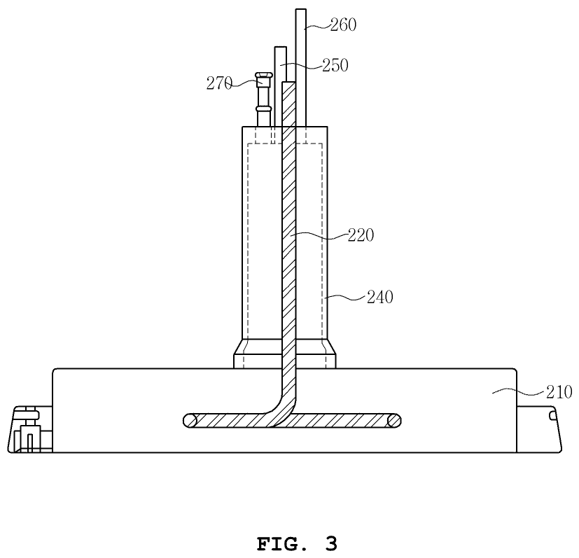

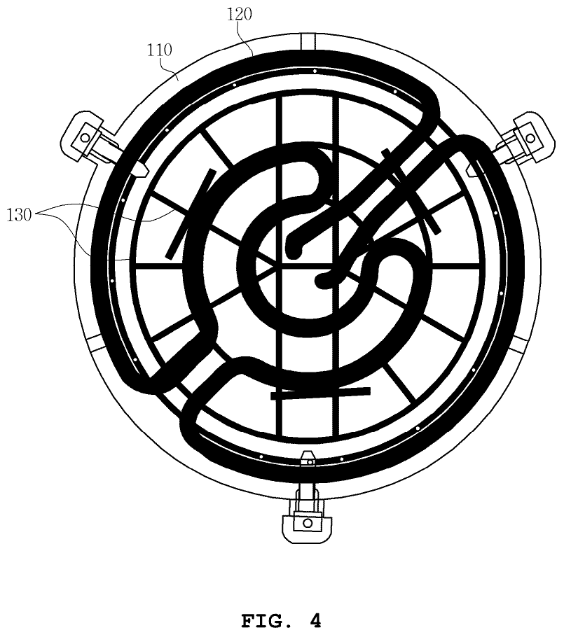

FIG. 3 is one construct view conceptually and briefly showing the basic constitution of a pedestal heater block in which a hot wire in a cartridge mode having an asymmetrical structure is adopted according to one exemplary embodiment of the present invention, and FIG. 4 is schematic plane view showing a form in which the hot wire in the cartridge mode is installed asymmetrically according to another exemplary embodiment of the present invention.

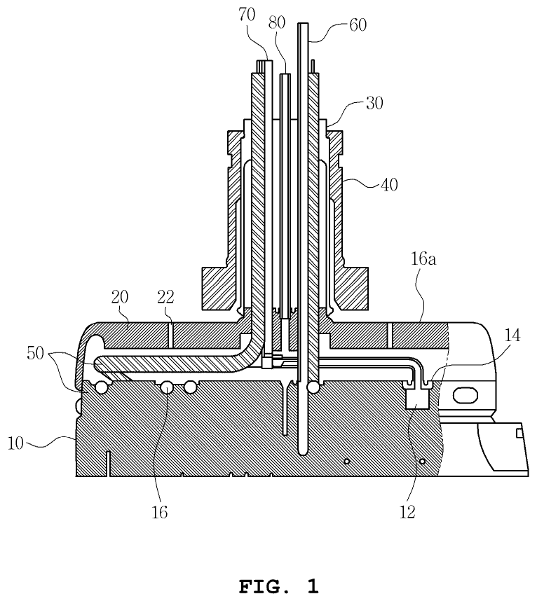

With respect to a general constitution, there is no large difference between the constitution shown in FIG. 1, and the constitution of the pedestal heater block according to the present invention, and referring to the drawing, a part of an inner rod 240 is connected onto a central part of the heater block 210 or a base block, and the hot wire 220 of a cartridge-type heater is installed in the heater block 210 by extending from an inner side of the inner rod 240. Also, a wafer chucking pipe 260 configured to cause a vacuum which holds a wafer (a substrate) to be applied, and an argon gas supply pipe 250 are installed in such a form as to be connected to the inner rod 240 from the outside, and a temperature sensor pipe 270 is also installed.

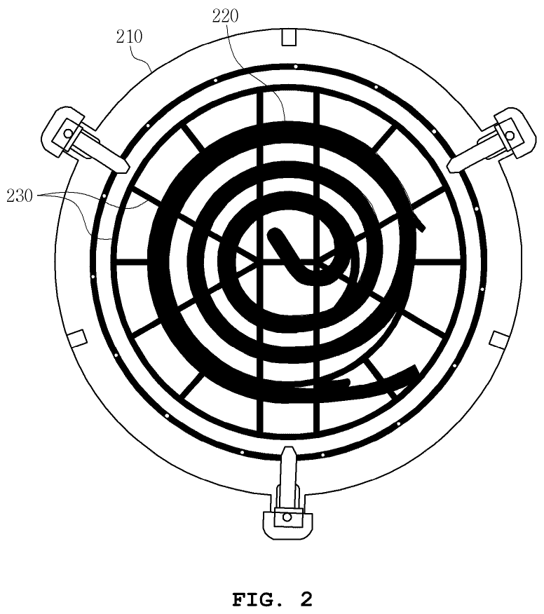

Here, the general constitution of the pedestal heater block is commonly formed in light of many parts in comparison with the constitution of the existing heater block, wherein it may be found that an arrangement form of the hot wire installed in the heater block is changed from a form shown in FIG. 2 in which the hot wire is arranged to be evenly distributed in a neighborhood part and a central portion while causing right and left points to be symmetrical with respect to the origin to a form in which the hot wire is arranged in a snail form like a snail shell, or an asymmetrical form like a whirlpool.

Also, here, the hot wire based on the conventional art is changed from a form in which a terminal configured to let an electric current come in, and a terminal configured to let an electric current go out are separately formed on both sides, namely, a sheath form in which the wire is arranged in a single fold, to a form in which a terminal configured to let an electric current come in, and a terminal configured to let an electric current go out are formed on only one side in such a manner as to put one upon another, namely, a cartridge form in which the wire is formed in two folds. Since this cartridge form causes an installation form to be designed conveniently when the hot wire 220 is installed in the asymmetrical form, in this case, it may be used more usefully.

Even though the snail form is similar to a concentric circle with respect to the form thereof, there is a difference in light of the fact that all the sections of the hot wire 220 are connected to one another, and the hot wire is indicated in a shred of line that turns and finishes in a direction similar to the circumferential direction while straying away from a direction of the center to an outer side, namely, showing multiple-turning. With respect to the hot wire in this snail form, a distance between a hot-wire section of the inner side, and a hot-wire section of the outer side adjacent thereto may be realized uniformly, and a connection with an external power source may be realized through an end part of the hot wire located at a central part of the heater block.

With respect to the heater block 210 which forms a circle when seen from a plane figure, a straight line which radially extends from the center to the neighborhood thereof, and a circle which connects the tip of a neighborhood part side of this straight line into the circumferential direction may represent a groove 230 on which the wafer is put, and which is formed on a surface of the heat block 210, and the tip in a direction of the center of the straight line which radially extends may be connected to a vacuum hole in the center intended for vacuum absorption. Accordingly, instantaneous pressure for the vacuum absorption of the wafer may act upon the whole of a back surface of the wafer via the groove 230.

Here, dimensions of the groove formed on the surface of the heater block may increase and reduce according to a position or an area so that width and depth of the groove cause temperature uniformity to be amended according to backside pressure. In order to improve pressed adhesion force when the backside pressure applied to a back side of the wafer during a process is maintained in a range of 3 torr or below, compared with the width and depth shown in the groove according to the conventional art, by making the width increase, and making the depth reduce, namely, on the assumption that a conventional section of the groove is a section similar to a perfect square whose width ranges from 1.2 mm to 1.9 mm, and whose depth ranges from 1.2 mm to 1.9 mm, according to the present invention, the width may be formed in the range of about 2.3 mm to 3.0 mm, for example, by increasing up to about 1 to 1.5 times, for example, and the depth may be formed in the range of about 0.5 mm to 1.0 mm, for example, by reducing up to about 0.3 to 0.6 time, for example, so the width can be formed to be greater than the depth.

A large number of gas supply holes as well as the grooves 230 are installed on the surface of the heater block 210, thereby being distributed upon the whole of the surface. Inert gas, like argon or helium, is mainly used in gas supplied from the gas supply holes.

Although heat of many parts is transmitted through direct conduction to the wafer to be put on the heater block, the hot wire exists as a line, the surface of the heater block exists as a face, so the hot wire may not be distributed perfectly and uniformly on the whole surface of the heater block, and accordingly, although the heat block is made of a material, like aluminum having excellent thermal conductivity, a temperature deviation resulting from each change in position may occur.

The gas discharged from the gas supply holes forms an atmospheric current by moving while coming into contact with the surface of the heater block and the back side of the wafer from a space therebetween, and this atmospheric current is discharged via the grooves and vacuum holes while producing a loss of heat at a place partially having a high temperature during the movement of the gas, and functioning to provide a place partially having a low temperature with the heat.

Magnitude of the backside pressure may be adjusted through the course of the whole process, and since the backside pressure very reduces up to 3 torr or below, for example, during the process, when vacuum absorption occurs powerfully, in the direction of the central part in which the vacuum holes exist, the wafer comes into closer contact with the surface of the heater block while deforming partially, and thus, the gas is discharged from the central part via the gas supply holes, and fails to flow smoothly through a space between the heater block and a substrate, so it is difficult for the gas to function as gas for temperature uniformity.

As a result thereof, a case in which a temperature of the wafer of the central part is maintained to be lower compared with the other parts occurs, and the present invention reaches a settlement of this temperature imbalance by making installation density of the hot wire higher in a side of the central part of the heater block compared with in the neighborhood part thereof. That is, as the gas fails to move smoothly, although the supply of heat via the gas reduces, the hot wire is concentrated and arranged on the central part so that transmission of the heat via conduction can be carried out more frequently, and thus, a temperature deviation can entirely reduce.

According to the present invention, in the whole of the circular heater block, based on one point which is in the range of ⅔ to ⅗ of a radius, for example, from the center, the hot wire which realizes the snail form is mainly distributed in a central part corresponding to an inner side thereof, and in a neighborhood part corresponding to an outer side thereof, even though there is a section in which one tip of the hot wire distributed asymmetrically extends partially to the neighborhood part, this section has no large effect on the whole.

Accordingly, with respect to the hot wire 220 shown in the exemplary embodiment of FIG. 4, when it is fixed that a central part is a section which reaches one point in the range of ⅔ to ⅗ of the radius from the center of the circular heater block, the hot wire is installed in a snail form to which the central part is limited, and shows such a form as to be hardly distributed in an outer side thereof.

Although there may be some differences according to each condition, since the wafer put on the heater block has a radius which is almost identical to that of the heater block, or is somewhat smaller than that of the heater block in the range of about 10%, when an area in which the hot-wire sections are concentrated is reduced to have about ½ of the radius from the center of the heater block, a temperature in the area of a neighborhood part thereof may reduce to be rather lower than that in the area of the central part, and accordingly, when the area in which the hot wire sections are concentrated is fixed, installation density of the hot wire should increase in an inner side of the hot wire on the basis of a point which reaches ½ or more of the radius at the lowest estimate. On the contrary, when the area in which the hot-wire sections are concentrated is fixed to be the inner side of the hot wire on the basis of a point which reaches ⅘ or more of the radius from the center, a temperature of the neighborhood part is still higher compared with that of the central part, so it may fail to sufficiently reduce a temperature deviation.

Of course, unlike the hot-wire sections according to the present exemplary embodiment, although some hot-wire sections may also be distributed in the outer side according to circumstances, the hot wire is installed to have lower installation density than that shown in the central part. It may be found that the distribution of the hot-wire sections is different from that shown in the conventional exemplary embodiment in which the hot wire is also installed in the neighborhood part of a double external angle of the heater block in such a manner that the hot wire sections are relatively uniformly divided in proportion when seen in a radius direction while having a conventional symmetrical form as shown in FIG. 2.

Based on this constitution, the hot wire is first formed in a cartridge form of a simple linear form in which the hot wire overlaps, and the hot wire is then formed in the snail form in such a manner that while deforming, the hot wire in the cartridge form showing a simple linear form is inserted into and fixed to the grooves in which the hot wire in the snail form arranged at a base block of the heater block is installed. At this time, a terminal of the hot wire which is bent may pass through a through hole of a block back cover, and may be connected to an external power source via a rod center in a backward direction thereof.

Meanwhile, the grooves are installed in a separate flat board-type jig in a form like that of the grooves which is located in the base block of the heater block, and in which the hot wire in the snail form is installed, the hot wire in the simple linear form deforms while being inserted thereto, thereby being formed in the snail form, and the hot wire in the snail form formed as described above is totally and completely inserted into and combined with the grooves configured to install the hot wire in the snail form, and in the same manner as that shown in the previous exemplary embodiment, this constitution may be realized using a method of combing the block back cover with the base block.

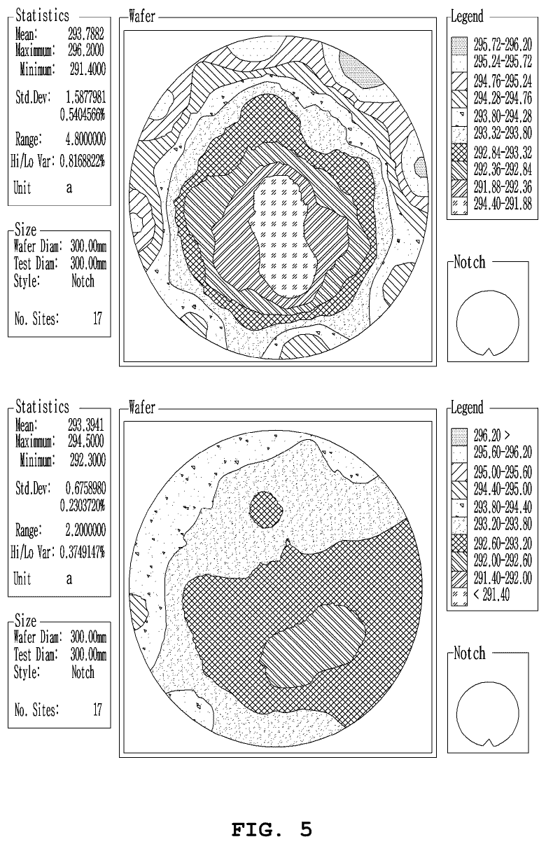

FIG. 5 is a temperature distribution-based comparative view showing temperature distributions together so that the temperature distributions can be compared with each other in such a manner as to vary color tones according to each temperature when heat is transmitted to the wafer on the basis of the exemplary embodiment shown in FIG. 2 according to the conventional art, and the exemplary embodiment shown in FIG. 4 according to the present invention. On the basis of the drawing, one photograph in the upper direction shows a case to which the present invention is applied, the other photograph in the lower direction shows a case to which the conventional art is applied.

In the case to which the conventional art is applied, it may be found that a section which shows a low temperature in a somewhat lower direction from the center of the wafer shown in the photograph is represented in a long oval which extends in upward and downward directions, and that a section which shows a high temperature is represented in directions of right and left neighborhood parts of the upper part of the wafer.

In the case in which the heater block as shown in the exemplary embodiment based on FIG. 4 is used, although a section which shows a low temperature is still shown in a little lower direction from the center of the wafer, in this case, it may be found that the section is represented in a long elliptical form which extends in right and left directions, and a section which shows a high temperature in directions of right and left neighborhood parts of the upper part of the wafer is represented not to be notable.

With respect to this result, it is hereinafter described in more detail with reference to comparative data based on the conventional art.

First, with respect to a chemical vacuum deposition machine named Green PD12, an experiment for comparing effects with one another was carried out using equipment which is installed in such a manner that each test wafer is put on a heater block in which the hot wire in the snail form having a hot-wire distribution in a symmetrical form as shown in FIG. 2 is installed, and another heater block in which the hot wire in the cartridge form having a hot-wire distribution in an asymmetrical form like a snail form as shown in FIG. 4 is installed, so a condition in which a fixed temperature is 300° C., and pressure of a process chamber is 10/40 torr could be applied thereto, and a condition in which backside pressure applied onto a back side of each test wafer is 3/5/20 torr could be applied thereto.

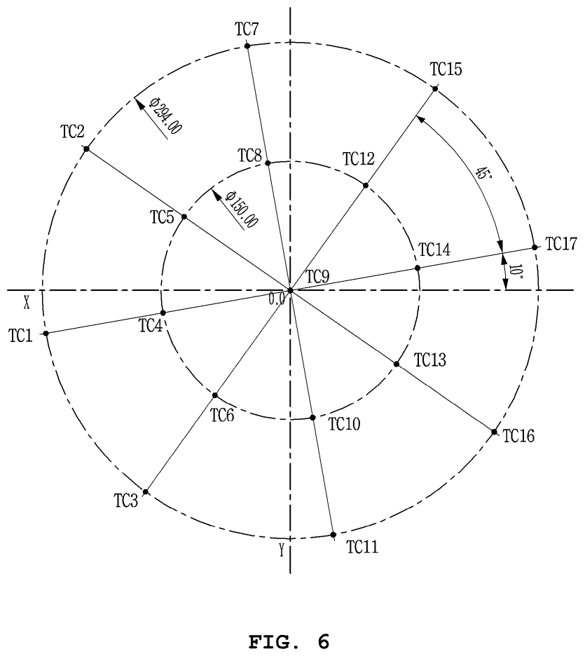

First, raw data resulting from measuring temperatures at each position which reaches TC17 from TC1 of the test wafer shown in FIG. 6 under an existing pressure condition which showed a serious temperature deviation, and in which pressure of the chamber is 10 torr, and a condition in which backside pressure is 3 torr were obtained as shown in Table 1.

TABLE 1

| | Case of | | |
|---|---|---|---|
| | Conventional | Case of Present | Temperature |
| | Exemplary | Exemplary | Difference |
| Position | Embodiment | Embodiment | Value |
| TC1 | 295.3 | 294.5 | −0.8 |
| TC2 | 295.4 | 294.4 | −1.0 |
| TC3 | 294.4 | 294.0 | −0.5 |
| TC4 | 292.4 | 292.9 | 0.5 |
| TC5 | 293.3 | 293.8 | 0.5 |
| TC6 | 292.1 | 292.7 | 0.6 |
| TC7 | 295.7 | 294.2 | −1.5 |
| TC8 | 292.9 | 293.1 | 0.2 |
| TC9 (CENTER) | 291.4 | 293.1 | 1.7 |
| TC10 | 291.4 | 292.4 | 1.0 |
| TC11 | 294.7 | 293.7 | −1.0 |
| TC12 | 293.7 | 293.4 | −0.3 |
| TC13 | 292.3 | 292.3 | 0.0 |
| TC14 | 292.9 | 293.0 | 0.1 |
| TC15 | 296.2 | 294.0 | −2.2 |
| TC16 | 294.5 | 293.2 | −1.3 |
| TC17 | 295.8 | 293.0 | −2.8 |

The result thereof was obtained as summarized in Table 2.

TABLE 2

| | | | | | Degree of | |
|---|---|---|---|---|---|---|
| | | | | | Non- | |
| | Maximum | Minimum | Temperature | Average | Uniformity | |
| Subject Area | Temperature | Temperature | Deviation | Temperature | (%) | Remark |
| Case of | 296.2 | 291.4 | 4.8 | 293.8 | 0.81 | reference |
| Conventional | | | | | | data |
| Exemplary | | | | | | |
| Embodiment | | | | | | |
| Case of | 294.5 | 292.3 | 2.2 | 293.4 | 0.37 | result of |
| Present | | | | | | change |
| Exemplary | | | | | | |
| Embodiment | | | | | | |
| Deviation | −1.7 | 0.9 | −2.6 | −0.4 | −0.44% | |

Referring to Table 2, with respect to the heater block showing the conventional hot-wire distribution, under the condition that a fixed temperature of the chemical vapor deposition machine was 300° C., the maximum temperature registered 296.2° C. at an upper right-side among positions of the wafer, the temperature in the neighborhood thereof was generally high, the neighborhood parts showed generally a high temperature, the minimum temperature registered 291.4° C. in the section of a central part TC9 and a central lower-part TC10, and the temperature of the central part was generally low. A temperature deviation read 4.8° C., the average temperature registered 293.8° C., and a degree of uniformity reached 0.81%.

With respect to the heater block showing the hot-wire distribution based on the exemplary embodiment of the present invention, under the condition that the fixed temperature of the same chemical vapor deposition device was 300° C., the maximum temperature registered 294.5° C. at a left side among positions of the wafer, the temperature in the neighborhood thereof was generally high, the temperature of the neighborhood parts was generally somewhat high, the minimum temperature registered 292.3° C. in the section located in the central part of a right lower-side TC13, and the temperature of the central part was generally somewhat low. However, with respect to the section where the temperature was higher compared with that shown in the conventional exemplary embodiment, the temperature reduced up to about 1.7° C. considerably, and with respect to the section where the temperature was low, the temperature increased up to about 0.9° C. slightly, so a temperature deviation reduced as much as 2.6° C. considerably, the average temperature read 293.4° C., thereby having no large change, and the uniformity became smaller up to 0.37%.

In general, the temperature can be found to reduce considerably in the section having the high temperature according to the existing exemplary embodiment, and the temperature deviation can be found to reduce considerably because the temperature increased slightly compared with the section having the low temperature shown in the existing exemplary embodiment. Of course, as the temperature deviation reduces gradually, the thickness deviation of a deposited material according to each position of the wafer also reduces, so a faulty rate can reduce, and a yield can be improved.

Table 3 below is based on enlarging the result shown in Table 2, and enables comparison to be carried out based on a result obtained in such a manner as to obtain and summarize the raw data concerning the temperatures according to each position of the wafer under another process chamber pressure and backside pressure. That is, for the comparison, the result is further shown on the basis of a case (CASE 1) resulting from mixing of the condition that the process chamber pressure is 10 torr, and the condition that the backside pressure is 3 torr, a case (CASE 2) resulting from another mixing of the condition that the process chamber pressure is 10 torr, and the condition that the backside pressure is 5 torr, and a case (CASE 3) resulting from the other mixing of the condition that the process chamber pressure is 40 torr, and the condition that the backside pressure is 20 torr.

TABLE 3

| | Process | | | | Present | |
|---|---|---|---|---|---|---|
| Subject | Chamber | Backside | Sub-Subject | Conventional | Exemplary | |
| Area | Pressure | Pressure | Area | Case | Embodiment | Difference |
| CASE 1 | 10 torr | 3 torr | Maximum | 296.2 | 294.5 | −1.7 |
| | | | Temperature | | | |
| | | | Minimum | 291.4 | 292.3 | 0.9 |
| | | | Temperature | | | |
| | | | Temperature | 4.8 | 2.2 | −2.6 |
| | | | Deviation | | | |
| | | | Average | 293.8 | 293.4 | −0.4 |
| | | | Temperature | | | |
| CASE 2 | 10 torr | 5 torr | Maximum | 296.7 | 295.6 | −1.1 |
| | | | Temperature | | | |
| | | | Minimum | 293.4 | 293.5 | 0.1 |
| | | | Temperature | | | |
| | | | Temperature | 3.3 | 2.1 | −1.2 |
| | | | Deviation | | | |
| | | | Average | 295.2 | 294.7 | −0.5 |
| | | | Temperature | | | |
| CASE 3 | 40 torr | 20 torr | Maximum | 299.2 | 297.6 | −1.6 |
| | | | Temperature | | | |
| | | | Minimum | 296.9 | 295.4 | −1.5 |
| | | | Temperature | | | |
| | | | Temperature | 2.3 | 2.2 | −0.1 |
| | | | Deviation | | | |
| | | | Average | 298.1 | 296.9 | −1.2 |
| | | | Temperature | | | |

Referring to this Table 3, when compared with the exemplary embodiment in which the hot-wire distribution is changed into the snail form, namely, the asymmetrical form, in the conventional case, it may be found that since the backside pressure is high, a temperature level of the wafer generally approaches the fixed temperature, 300° C. as a degree of vacuum absorption reduces gradually, and the temperature deviation is not large, and in case that the heater block based on the constitution of the present invention resulting from changing the form of the hot wire is applied thereto, although an effect of improvement of the temperature deviation occurs in all cases, it may be found that an effect of a settlement of the temperature deviation occurs largely as the backside pressure reduces gradually.

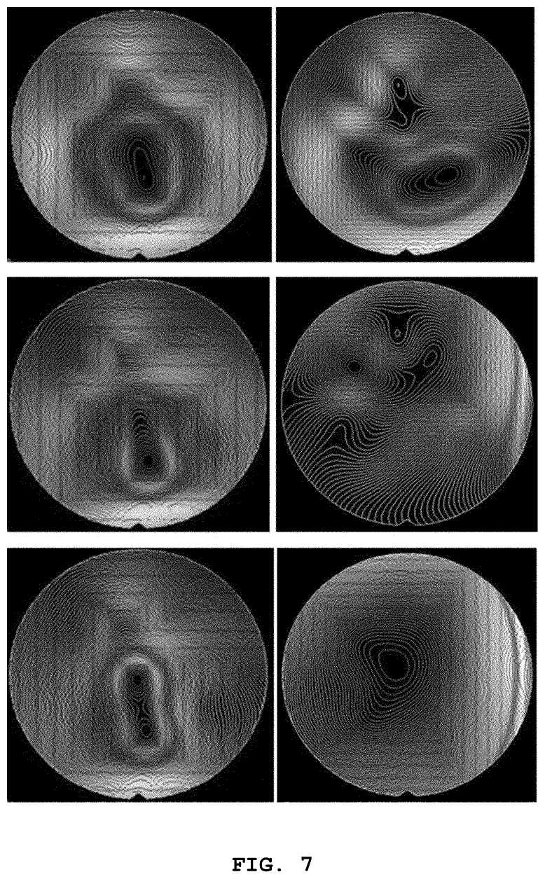

FIG. 7 is photographs concerning heat distributions of the wafer, which show the result of experiments related with Table 3, and they represent a case in which the backside pressure is 3 torr from the uppermost photograph, a case in which the backside pressure is 5 torr from the central photograph, and a case in which the backside pressure is 20 torr from the lower photograph, wherein on the whole, the conventional cases are indicated on the left side, and the cases according to the exemplary embodiment of the present invention are indicated on the right side. Heat distribution forms which are entirely coincident with those shown in Table 3 may be found. That is, it may be found that as vacuum adsorption force from the heater block with respect to the wafer becomes higher due to the low backside pressure, a temperature deviation occurs remarkably, and when the heater block according to the present invention is applied, it is effective to improve the temperature deviation.

As described previously, although the present invention has been described based on the limited exemplary embodiments, the embodiments have exemplarily been described for understanding of the present invention, and the present invention should not be construed as being limited to the exemplary embodiments set forth.

Accordingly, based on the present invention, it should be understood that various modifications and applied examples can be realized by those having ordinary skill in the field to which the present invention pertains, and that the modifications and the applied examples belong to the scope of the appended claims.

1. A pedestal heater block having an asymmetrical hot-wire structure, with respect to the pedestal heater block for a chemical vapor deposition machine, in which a structure intended for causing a vacuum to be applied is installed on a surface so that a wafer can be fixed by vacuum absorption, and which comprises:
gas supply holes distributed to supply gas for temperature uniformity onto a back side of the wafer; and
a hot wire configured to apply heat to the wafer,
wherein backside pressure applied to the back side of the wafer by the structure of causing the vacuum to be applied and the gas supply holes is fixed to be 3 torr or below of low pressure, the heater block is composed of aluminum or an aluminum alloy, and the hot wire is composed in a cartridge form,
wherein the hot wire is installed to have higher installation density in a central part of the heater block than that in a neighborhood part which is an outer side of the heater block.

2. The pedestal heater block of claim 1, wherein grooves formed on a surface of the heater block each show that width is formed to be 2 to 6 times wider than depth, the width ranging from 2.3 mm to 3.0 mm, and the depth ranging from 0.5 mm to 1.0 mm, so that a pressed adhesion can be improved when the backside pressure applied onto the back side of the wafer during a process is maintained in a range of 3 torr or below.

3. The pedestal heater block of claim 1, wherein the central part of the heater block is set on the basis of a point which is within a range of ⅗ to ⅔ of a radius from the center of the circular heat block, the outer side of the heater block forms the neighborhood part.

4. The pedestal heater block of claim 1, wherein the hot wire is configured in a snail form which is an asymmetrical form to be distributed only within the central part.

5. The pedestal heater block of claim 2, wherein the hot wire is configured in a snail form which is an asymmetrical form to be distributed only within the central part.
